(19) United States
(12) Patent Application Publication
(10) Pub. No.: US 2018/0123612 A1
(43) Pub. Date: May 3, 2018

(54) DATA REDUCTION METHOD AND APPARATUS

(71) Applicant: SIEMENS AKTIENGESELLSCHAFT, Muenchen (DE)

(72) Inventors: Alexander Pyayt, St. Petersburg (RU); Sergey Zobnin, St. Petersburg (RU)

(21) Appl. No.: 15/565,075

(22) PCT Filed: Apr. 8, 2015
(86) PCT No.: PCT/RU2015/000229

§ 371 Date: Oct. 6, 2017

(51) Int. Cl. H03M 7/30; H04N 19/51

(52) U.S. Cl. CPC H03M 7/6058; H04N 19/51; H03M 7/3059

(57) ABSTRACT

A data reduction for reducing highly correlated data (e.g., highly correlated data streams) is provided. Correlated data of a plurality of data streams are identified, and a spectral dimensional decomposition is performed. In this way, information from the data of the data streams may be exploited, and this information may be used in order to achieve a highly efficient reduction of the data. In this way, the compression ratio of the data may be enhanced or the data loss of the reduce data compression may be minimized.

This application is the National Stage of International Application No. PCT/RU2015/000229, filed Apr. 8, 2015,

### BACKGROUND

The present embodiments relate to reducing data.

Many modern technical systems deal with a high amount of digital information. For example, the amount of digital information that is produced by modern technical systems increases more and more rapidly. For example, the resolution of images becomes higher, or measurement data provided by sensors supervising a technical system increase by increasing the number of sensors and/or the resolution of each sensor. In many cases, data is highly correlated or even similar. For example, a plurality of images may have a common image database, or a plurality of redundant sensors are monitoring a same object. This increasing amount of data leads to at least the following two problems: a large amount of data is to be stored; and a large amount of data is to be transmitted between a data source and further components for processing the data. Conventional compression algorithm may only provide limited compression rates.

### SUMMARY AND DESCRIPTION

There is a need to get along with an increasing amount of data. Consequently, there is a need to reduce the amount of data (e.g., to reduce an amount of highly correlated data).

According to a first aspect, a data reduction method includes obtaining data and identifying groups of correlated data in the obtained set of data. Further, the method performs a spectral dimensionality decomposition for the groups of correlated data in order to obtain spectral decomposition components and factors. The obtained spectral decomposition components and factors are output.

According to a further aspect, a data reduction apparatus for reducing an amount of data in a set of data is provided. The apparatus includes a similarity identification unit configured to identify groups of correlated data in the set of data. The data reduction apparatus further includes a spectral dimensionality decomposition unit configured to perform a spectral dimensionality decomposition for the groups of correlated data and to provide spectral decomposition components and factors.

One or more of the present embodiments take into account that data very often is highly correlated or similar. For example, the data of technical systems like redundant sensors monitoring the same object will be very similar. For example, a plurality of sensors monitoring the same object may only differ by an amplitude or a phase.

One or more of the present embodiments take into account this observation and provide enhanced data reduction for such highly correlated data. For example, one or more of the present embodiments provide a data reduction apparatus and method that exploit information from the data to be compressed. A much better compression ratio may thus be achieved than by compressing data using conventional or standard compression methods. By taking into account information in the data itself during the data reduction, a high compression ratio may be achieved while maintaining a high quality after reconstructing the reduced data. Even though a loss or data compression is applied to the original data, the loss of information during the compression and reconstruction is low.

According to an embodiment, the set of data that is obtained for data reduction includes a plurality of data streams.

According to a further embodiment, the act of obtaining a set of data includes obtaining data from a plurality of sensors. However, further data sources for providing data streams may be provided.

By subjecting data from a plurality of data streams (e.g., a plurality of highly correlated data streams) to the above-described data reduction, a very efficient reduction of data may be achieved with a minimum loss of information. In this way, technical systems for monitoring complex apparatus may be possible, even though the resources for storing and/or data transmission may be limited.

According to a further embodiment, the groups of identified correlated data include groups of correlated data streams.

The data to be reduced is thus divided into a plurality of correlated data streams. Such a plurality of correlated data streams may be subjected to a very efficient data reduction.

According to a further embodiment, the act of identifying groups of correlated data includes linear correlation calculation, or a cluster analysis. For example, the act of identifying groups of correlated data may include density-based clustering or centroid-based clustering.

Such an identification of correlated data by a correlation value or a cluster analysis is a very efficient method for identifying similarities in the data to be reduced.

According to a further embodiment, spectral dimensionality decomposition includes principal component analysis, independent component analysis, and/or local component analysis.

Such a spectral dimensionality decomposition is a very efficient method for specifying the characteristics of a plurality of series of data.

According to a further embodiment of the data reduction apparatus, the apparatus further includes a memory for storing the spectral dimensionality decomposition components and factors, and the reconstruction unit is configured to reconstruct the set of data based on the stored spectral decomposition components and factors in the memory.

In this way, the amount of data may be reduced before storing the data. Hence, the required storage capacity of the memory may be reduced even though the data may be provided in high quality after reading and reconstruction.

According to a further embodiment, the apparatus further includes a transmitting unit configured to transmit the spectral decomposition components and factors.

Hence, a high amount of data may be transmitted via a transmission line providing only a limited bandwidth.

According to a further aspect, one or more of the present embodiments provide a data reconstruction apparatus including a receiving unit configured to receive spectral decomposition components and factors transmitted by a data reduction apparatus. The data reconstruction apparatus also includes a reconstruction unit configured to reconstruct the set of data based on the received spectral decomposition components and factors.

In this way, the data may be provided in a high quality after transmitting a high amount of data via a transmission line providing only a limited bandwidth.

According to a further aspect, one or more of the present embodiments provide a measurement system including a plurality of sensors, where each sensor is configured to provide a data stream. The measurement system includes a data reconstruction apparatus. The data reconstruction apparatus is configured to perform a data reduction of data streams provided by the plurality of sensors of the measurement system.

According to a further aspect, one or more of the present embodiments provide a computer program product configured to perform the data reduction method.

### BRIEF DESCRIPTION OF THE DRAWINGS

FIG. 1 shows a schematic illustration of a data reduction apparatus according to an embodiment; and

FIG. 2 shows a flowchart of a data reduction method underlying a data reduction method according to an embodiment.

### DETAILED DESCRIPTION

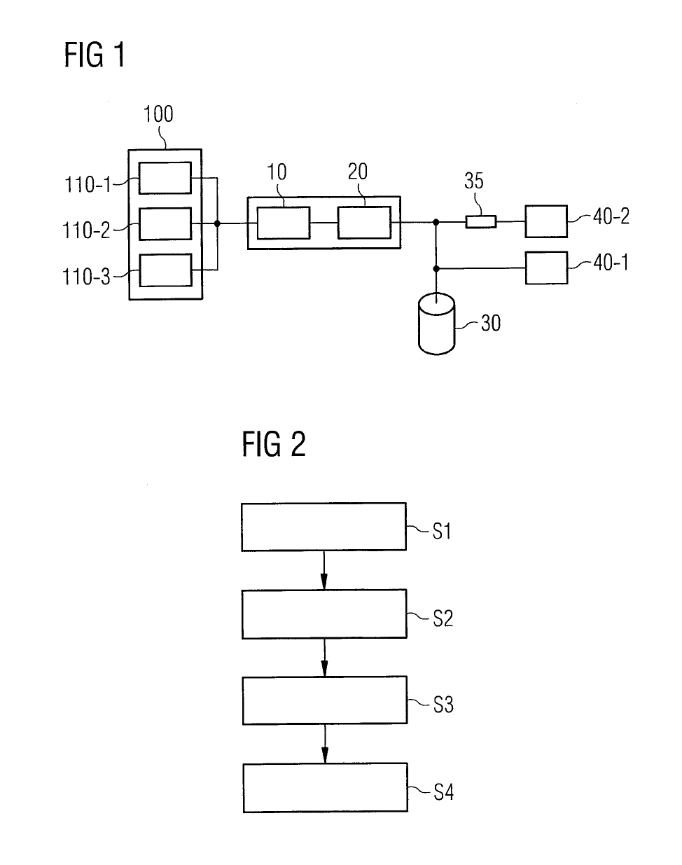

FIG. 1 shows a schematic illustration of one embodiment of a data reduction apparatus for reducing an amount of data provided by a data source 100. For example, the data source 100 may be any technical system, such as a manufacturing facility, a power plant (e.g., a gas turbine), etc. Such a technical system may be monitored by a plurality of sensors 110-i. In order to enhance the reliability of the data provided by the sensors 110-i, a plurality of redundant sensors may be employed in some cases. In this case, the data output by the redundant sensors 110-i may be similar or almost the same. However, it may be also possible that output signals of different sensors 110-i are correlated too. For example, a first sensor 110-i may monitor a voltage, and a second sensor 110-i may monitor a current. Further, a third sensor may monitor the rotational speed of a generator providing the monitored voltage and current. In such a case, there will also be some similarities between rotational speed, current, and voltage. Even though there are only three sensors shown in FIG. 1, the data source 100 may include more sensors 110-i, and the present embodiments are not limited to only three sensors 110-i. Additionally, the present embodiments are also not limited to sensors for monitoring voltage, current, or rotational speed. Any other type of sensor or data source providing digital information or analog information that is converted to digital information by an analog to digital converter may be provided.

In one embodiment, the data output by the sensors 110-i of the data source 100 are provided as continuous data streams. However, the data is not limited to data streams. Any other format of data may also be provided.

In order to reduce the amount of data provided by the data source 100, the data is provided to a data reduction apparatus. The data reduction apparatus may be formed by one or more processors. The data reduction apparatus may include at least a similarity identification unit 10 and a spectral dimensionality decomposition unit 20. The similarity identification unit 10 receives the data provided by data source 100. If necessary, all data (e.g., all data streams of the individual sensors 110-i) may be adapted. For example, the resolution, the sampling rate, etc. may be adapted in order to obtain a unique basis for all input data.

Similarity identification unit 10 analyzes the obtained data form data source 10 to identify groups of correlated data. For example, similarity identification unit 10 of the data reduction apparatus may perform a linear correlation calculation. In order to identify groups of correlated data in the data obtained from the data source 100, a correlation value of the individual data segments or data streams from the data source 100 may be calculated. If the correlation value exceeds a predetermined value, the data is considered to be similar. Such groups of a data are identified as correlated data. However, any other method for determining groups of correlated data may be provided.

For example, a cluster analysis of the obtained data from data source 100 may also be performed. Cluster analysis is a task of grouping a set of objects such that objects in the same group are more similar to each other than to objects in other groups. It is a main task of exploratory data mining, and a common technique for statistical data analysis, used in many fields.

Cluster analysis may be achieved by various algorithms that differ significantly in a notion of what constitutes a cluster. Popular notions of clusters include groups with small distances among the cluster members, dense areas of the data space, intervals, or particular statistical distributions. Cluster analysis may therefore be formulated as a multi-objective optimization problem. The appropriate clustering algorithm and parameter settings depend on the individual data set and intended use of the results. Cluster may be an iterative process of knowledge discovery or interactive multi-objective optimization that involves trial and failure. Data preprocessing and model parameters may be modified until the result achieves the desired properties.

For example, density-based clustering or a centroid-based clustering may be used to identify similarities in the obtained data from the plurality of sensor data from sensors 110-i.

In centroid-based clustering, clusters are represented by a central vector that may not necessarily be a member of the data set. For example, when the number of clusters is fixed to k, k-means clustering gives a formal definition as an optimization problem: find the k cluster centers and assign the objects to the nearest cluster center, such that the squared distances from the cluster are minimized.

The common approach is to search only for approximate solutions. An example of a known approximatively method is Lloyd's algorithm, which is also referred to as “k-means algorithm”. Variations of k-means may include optimizations as choosing the best of multiple runs, but also restricting the centroids to members of the data set, choosing medians, choosing the initial centers less randomly, or allowing a fuzzy cluster assignment.

In density-based clustering, clusters are defined as areas of higher density than the remainder of the data set. Objects in these sparse areas (e.g., required to separate clusters) may be considered to be noise and border points. A well-known density based clustering method is density-based spatial clustering of applications with noise (DBSCAN).

Even though it is possible to apply the data reduction according to one or more of the present embodiments to periodical time streams, the present embodiments are not limited to such periodical time streams. Non periodical data streams are also possible.

A spectral dimensionality reduction is applied to the identified correlated data in spectral dimensional data composition unit 20. For example, a principal component analysis may be applied to the identified groups of correlated data. Such a principal component analysis (PCA) is a statistical procedure that uses an orthogonal transformation to convert a set of observations of possibility correlated variables into a set of values of linearity uncorrelated variables referred to as principal components. The number of principal components is less than or equal to the number of original variables. Hence, the amount of data may be reduced. The transformation is defined such that the first principal component has the largest possible variance, and each succeeding component has the highest variance possible under the constraint that is orthogonal to the preceding components.

After a principal component analysis of the identified correlated data has been performed, the first principal components are used to encode and decode data. In other words, principal components and the coefficients are output instead of the whole data provided by data source 100. In this way, the amount of data is reduced with respect to the data provided by the data source 100. Since highly correlated data are subjected to such a spectral dimensionality decomposition, the output data of the data reduction apparatus includes only the whole data (e.g., as encoded PCA components) of uncorrelated data streams, while the remaining data may be specified by a few additional principal components.

In other words, the data reduction apparatus first performs a training phase in order to identify similar sets of data (e.g., data streams). After such a training phase, only a single data stream is to be fully encoded, while the remaining data streams of a plurality of similar data streams are specified by only encoding deviations with respect to the transmitted data stream. Hence, a data reduction of a high amount of input data is performed by taking into account characteristics of the input data (e.g., with respect to the temporal sequence of the data streams). For a plurality of similar data streams, only a single data stream is to be transmitted or stored (e.g., in an encoded form), while the remaining data streams are transmitted or stored by encoding only deviations.

Even though the spectral dimensional decomposition has been described in the previous description with respect to a principal component analysis, it may be also possible to apply an independent component analysis (ICA) or a local component analysis (LCA). Further algorithms for spectral dimensionality decomposition may be used also.

After a data reduction has been applied to the data provided by the data source 100, the data may be transmitted via a transmission line 35 and/or stored in a memory 30. If the reduced data is stored in a memory 30, the reduced data may be reconstructed by reconstruction unit 40-1. In this case, reconstruction unit 40-1 reads the data from memory 30 and performs a reconstruction of the set of data based on the store spectral decomposition components and factors in this memory. After this, all data (e.g., data streams) may be provided in the original (e.g., uncompressed) format. Even though the data reconstruction, as described before, is a losy compression, there is only a minimum data loss since the compression of the data takes into account information from the data itself when reducing the amount of data.

According to an alternative embodiment, the data may be transmitted via a transmission line 35 after reducing the amount of data. In this case, the reduced data may be received by a receiving unit 40-2 at the other end of the transmission line 35, and subsequently, a reconstruction of the reduced data may be performed (e.g., with one or more processors) in order to obtain all data (e.g., data streams) in an original data format (e.g., uncompressed).

According to a further embodiment, the reduced data may be further processed without reconstruction. For example, the components and factors of the spectral dimensionality decomposition may be directly used for a further processing of the reduced data without uncompressing the encoded data. For example, if a subsequent processing may be required components and factors of a spectral dimensionality decomposition, it is not necessary to perform such a spectral decomposition again.

Hence, a subsequent analysis of the data may be performed based on the encoded data having a reduced amount of data. In this way, the previous processing of the data from data source 100 may be used in order to simplify and speed up a further processing. By using the data of the principal component analysis, the independent component analysis, or the local component analysis in a subsequent processing, it is not necessary to apply such an analysis once again.

FIG. 2 shows a flowchart illustrating a data reduction method according to an embodiment. In act S1, a set of data is obtained. The obtained data may be, for example, a plurality of data streams, such as data streams output by sensors 110-i of data source 100.

Subsequently, groups of correlated data may be identified in act S2. For example, the groups of identified data may include groups of correlated data streams.

The identification of groups of correlated data may be performed by a linear correlation calculation or a clustering. For example, the clustering may be a density-based clustering and/or a centroid-based clustering. Any other method for identifying correlated data may be provided also.

In act S3, a spectral dimensionality decomposition for the groups of correlated data is performed. In this way, spectral decomposition components and factors may be obtained. As already outlined above, the spectral dimensionality decomposition may be performed by a principal component analysis, an independent component analysis, and/or a local component analysis.

After this, the obtained spectral decomposition components and factors may be output in act S4 as encoded data. For example, the whole components and factors of a single element of the group of correlated data are output, while only components and factors specifying differences to this single element are output for the remaining elements of the group. The output spectral decomposition components may be stored in a memory 30 or may be transmitted via a transmission line 35.

One or more acts of the data reduction method shown in FIG. 2 may be executed by one or more processors.

In order to further deal with the data, a data reconstruction may be performed based on the components and factors of the spectral dimensionality decomposition. Alternatively, the spectral decomposition components and factors may be directly used for a further processing and analysis of the data.

Summarizing, the present embodiments provide a data reduction for reducing highly correlated data (e.g., highly correlated data streams). For this purpose, correlated data of a plurality of data streams are identified, and a spectral dimensional decomposition is performed. In this way, information may be exploited from the data of the data streams, and this information may be used in order to achieve a highly efficient reduction of the data. In this way, the compression ratio of the data may be enhanced, or the data loss of the reduce data compression may be minimized.

Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A data reduction method comprising:
obtaining a set of data;
identifying groups of correlated data in the set of data;
obtaining spectral decomposition components and factors, the obtaining of the spectral decomposition components and factors comprising performing a spectral dimensionality decomposition for the groups of correlated data; and
outputting the obtained spectral decomposition components and factors.

2. The method of claim 1, wherein the set of data comprises a plurality of data streams.

3. The method of claim 1, wherein the obtaining of the set of data comprises obtaining data from a plurality of sensors.

4. The method of claim 1, wherein the groups of identified correlated data comprise groups of correlated data streams.

5. The method of claim 1, wherein the identifying of the groups of correlated data comprises linear correlation calculation or a cluster analysis.

6. The method of claim 1, wherein the spectral dimensionality decomposition comprises principal component analysis, independent component analysis, local component analysis, or any combination thereof.

7. A data reduction apparatus for reducing an amount of data in a set of data, the data reduction apparatus comprising:
a similarity identification unit configured to identify groups of correlated data in the set of data; and
a spectral dimensionality decomposition unit configured to:
perform a spectral dimensionality decomposition for the groups of correlated data; and
provide spectral decomposition components and factors.

8. The data reduction apparatus of claim 7, further comprising a memory configured to store the spectral decomposition components and factors; and
a reconstruction unit configured to reconstruct the set of data based on the stored spectral decomposition components and factors in the memory.

9. The data reduction apparatus of claim 7, further comprising a transmitter configured to transmit the spectral decomposition components and factors.

10. A data reconstruction apparatus comprising:
a receiver configured to receive spectral decomposition components and factors transmitted by a data reduction apparatus for reducing an amount of data in a set of data, the data reduction apparatus comprising a similarity identification unit configured to identify groups of correlated data in the set of data, a spectral dimensionality decomposition unit configured to perform a spectral dimensionality decomposition for the groups of correlated data and provide spectral decomposition components and factors, and a transmitter configured to transmit the spectral decomposition components and factors; and
a reconstruction unit configured to reconstruct the set of data based on the received spectral decomposition components and factors.

11. A measurement system comprising:
a plurality of sensors, wherein each sensor of the plurality of sensors is configured to provide a data stream; and
a data reduction apparatus for reducing an amount of data in a set of data, the data reduction apparatus comprising a similarity identification unit configured to identify groups of correlated data in the set of data, and a spectral dimensionality decomposition unit configured to perform a spectral dimensionality decomposition for the groups of correlated data and provide spectral decomposition components and factors,
wherein the data reduction apparatus is adapted to perform a data reduction of the data streams provided by the plurality of sensors.

12. A computer program product comprising a non-transitory computer-readable storage medium storing instructions executable by one or more processors to reduce an amount of data, the instructions comprising:
obtaining a set of data;
identifying groups of correlated data in the set of data;
obtaining spectral decomposition components and factors, the obtaining of the spectral decomposition components and factors comprising performing a spectral dimensionality decomposition for the groups of correlated data; and
outputting the obtained spectral decomposition components and factors.

13. The computer program product of claim 12, wherein the set of data comprises a plurality of data streams.

14. The computer program product of claim 12, wherein the obtaining of the set of data comprises obtaining data from a plurality of sensors.

15. The computer program product of claim 12, wherein the groups of identified correlated data comprise groups of correlated data streams.

16. The computer program product of claim 12, wherein the identifying of the groups of correlated data comprises linear correlation calculation or a cluster analysis.

17. The computer program product of claim 12, wherein the spectral dimensionality decomposition comprises principal component analysis, independent component analysis, local component analysis, or any combination thereof.
